(19) United States
(12) Patent Application Publication
(10) Pub. No.: US 2008/0248430 A1
(43) Pub. Date: Oct. 9, 2008

(54) Process for preparing a nano-carbon material field emission cathode plate

(75) Inventors: Yih-Ming Liu, Taoyuan (TW); Yuh Sung, Taoyuan (TW); Ming-Der Ger, Taoyuan (TW); Yun-Chih Fan, Taoyuan (TW); Yu-Hsien Chou, Taoyuan (TW); Chun-Tin Lin, Taoyuan (TW)

Correspondence Address: BACON & THOMAS, PLLC, 625 SLATERS LANE, FOURTH FLOOR, ALEXANDRIA, VA, 22314-1176, US

(73) Assignee: NATIONAL DEFENSE UNIVERSITY, Taoyuan (TW)

(21) Appl. No.: 11/826,791

(22) Filed: Jul. 18, 2007

(30) Foreign Application Priority Data
Dec. 18, 2006 (TW) 95147527

(51) Int. Cl. B05D 5/12; C23C 14/34; G03F 7/20

(52) U.S. Cl. 430/311; 427/77; 204/192.17

(57) ABSTRACT

A nano-carbon material field emission cathode plate is prepared by an oxidation-reduction reaction, which includes immersing a substrate having a first metal layer thereon in a solution of a second metal salt with a nano-carbon material dispersed therein. A difference between the two standard redox potentials of the first metal and the second metal is so great that ions of the second metal in the solution are reduced to elemental metal while the first metal is oxidized, and thus a layer of the second metal is formed on the first metal layer with the nano-carbon material partially embedded in the second metal layer.

### FIELD OF THE INVENTION

The present invention is related to a process for preparing a nano-carbon material field emission cathode plate by oxidation-reduction reaction.

### BACKGROUND OF THE INVENTION

There have been more than one methods for synthesizing a nano-carbon material being successfully developed, namely the arc discharge method, laser vaporization method, and chemical vapor deposition method (CVD), etc., since Iijima et al. published an article introducing carbon nanotubes on Nature in 1991. This is because the excellent mechanical properties and field emission effect exhibited by the carbon nanotubes have attracted many researchers to focus their researches on this field. Among them CVD is recognized as the most convenient method to grow the nano-carbon material, which not only can uniformly grow the nano-carbon material on a substrate but the grown nano-carbon material is easy to be purified.

The industries are aggressively developing a large area field emission flat panel display. The most important step in fabricating the large area field emission flat panel display is growing a nano-carbon material on a large area glass substrate.

US 2003-0181328 A1 discloses a supported metal catalyst useful in synthesizing carbon nanotubes by low-temperature (<600° C.) thermal chemical vapor deposition (CVD), which contains particles of a noble metal having a diameter of 0.1-10 microns as a support and a metal catalyst deposited on the support. The metal catalyst selected from iron, cobalt, nickel and an alloy thereof is deposited by immersing the noble metal particles in an aqueous solution having ions of iron, cobalt or nickel, and reducing the ions with hydrazine. US 2003-0181328 A1 also discloses a method of synthesizing carbon nanotubes on a glass substrate, which comprises dispersing the supported metal catalyst on a glass substrate; and growing carbon nanotubes on said supported metal catalyst by low-temperature thermal CVD at 400-600° C.

US 2001/0025962 A1 discloses a field emission type cold cathode device using fullerene or carbon nanotube for emitter and a process for preparing the same, wherein a metal plating layer is formed on a substrate by an electroplating processing or electroless plating processing with an electroplating of or electroless plating bath having a carbon structure dispersed therein, wherein the carbon structure is selected from fullerenes and carbon nanotubes, and the carbon structure is stuck out from the metal plating layer with a part of the carbon structure being buried in the metal plating layer. The electroless plating bath is kept at an elevated temperature about 80° C., and it deteriorates after a period of time of using at such an elevated temperature, and thus increases the manufacturing cost. A non-uniform electric field occurs during the electroplating processing, creating a metal layer with non-uniform thickness, so that the evenness of filed emission is adversely affected.

### SUMMARY OF THE INVENTION

The present invention provides a process for preparing a nano-carbon material field effect emission cathode plate without drawbacks in the prior art

The features of the process of the present invention includes selecting an appropriate first metal as cathode lines on the cathode plate, and an appropriate second plate to be formed on the cathode lines with a nano-carbon material partially buried therein, so that the difference between the two standard redox potentials of the two metals is large enough to enable a chemical displacement reaction between the ions of the second metal and atoms of the first metal, thereby an electroplating processing or electroless plating processing as described in the above-mentioned US 2001/0025962 A1 is no longer required for forming a nano-carbon material which is stuck out from the cathode lines with a part of the carbon structure being buried in the cathode lines.

The process of the present invention includes immersing a substrate having a first metal layer thereon in a solution of a second metal salt with a nano-carbon material dispersed therein. Due to the difference between the two standard redox potentials (ΔE) of the first metal and the second metal, ions of the second metal in the solution are reduced to elemental metal while the first metal is oxidized, and thus a layer of the second metal is formed on the first metal layer with the nano-carbon material partially embedded in the second metal layer. The (ΔE) is greater than 200˜300 mV so that the oxidation-reduction can undergo at room temperature or elevated temperature. The process of the present invention is simple, easy and free from the disadvantages of the prior art electroplating processing and electroless processing.

### BRIEF DESCRIPTION OF THE DRAWINGS

FIG. 1 is a SEM photograph showing a composite layer of carbon nanotubes and nickel on a glass substrate prepared in Example 1 of the present invention.

FIG. 2 is a photograph showing a luminous effect by applying an electric voltage to an assembly of a carbon nanotube field emission cathode plate prepared in Example 1 of the present invention and an anode plate coated with fluorescent powder.

FIG. 3 is a photograph showing a luminous effect by applying an electric voltage to an assembly of a nano-diamond field emission cathode plate prepared in Example 2 of the present invention and an anode plate coated with fluorescent powder.

FIG. 4 is a photograph showing a luminous effect by applying an electric voltage to an assembly of a nano-carbon fiber field emission cathode plate prepared in Example 3 of the present invention and an anode plate coated with fluorescent powder.

FIG. 5 is a photograph showing a luminous effect by applying an electric voltage to an assembly of a carbon nanotube field emission cathode plate prepared in Example 4 of the present invention and an anode plate coated with fluorescent powder.

### DETAILED DESCRIPTION OF THE INVENTION

The present invention discloses a process for preparing a nano-carbon material field emission cathode plate comprising the following steps:

a) forming a layer of a first metal on a substrate; and

b) immersing the substrate in an aqueous solution of a salt of a second metal with a nano-carbon material dispersed therein to form a layer of the second metal on the first metal layer with the nano-carbon material partially embedded in the second metal layer, wherein, due to a difference between two standard redox potentials of the first metal and the second metal, ions of the second metal in the aqueous solution are reduced to elemental metal while the first metal is oxidized.

Preferably, the first metal is iron, cobalt, nickel, tin, zinc, aluminum or a mixture thereof; and the second metal is copper, gold, palladium, platinum, silver, nickel, cobalt, or a mixture thereof. More preferably, the first metal is aluminum.

In some of the preferred embodiments of the present invention the following combinations of the first metal and the second metal were used: zinc as the first metal, and nickel as the second metal; nickel as the first metal, and copper as the second metal; zinc as the first metal, and cobalt as the second metal; and aluminum as the first metal, and nickel as the second metal.

Preferably, step a) comprises forming the first metal layer on the substrate by sputtering deposition, evaporating deposition, or electroless plating.

Preferably, the first metal layer is formed by sputtering deposition.

Preferably, the first metal layer is formed by electroless plating.

Preferably, the process of the present invention further comprises:

c) removing the substrate from the aqueous solution, washing the substrate with water, and heating the substrate under vacuum to activate the nano-carbon material partially embedded in the second metal layer. Preferably, the heating is carried out at 200-500° C. for 10-60 minutes, and more preferably, at 400° C. for 10-30 minutes.

Preferably, the substrate is a glass substrate or a glass substrate with silicon deposited thereon.

Preferably, the nano-carbon material is carbon nanotube, nano-carbon fiber or nano-diamond.

Preferably, the aqueous solution in step b) is kept at a temperature of 60 to 80° C.

Preferably, the difference between two standard redox potentials of the first metal and the second metal is greater than 200 mV.

The aqueous solution of the second metal salt in step b) preferably contains 0.04-1 g of nano-carbon material per liter of the aqueous solution salt to achieve a desired field emission property. The aqueous solution may contain more nano-carbon material; however, the cost will be higher.

Preferably, the aqueous solution of the second metal salt in step b) may contain a surfactant or a dispersing agent to enhance the dispersion of the nano-carbon material in the aqueous solution. More preferably, the aqueous solution further contains a complexing agent. Most preferably, the aqueous solution contains a pH adjusting agent.

The surfactant for use in the present invention may be a cation surfactant, non-ionic surfactant or mixture thereof as long as it does not adversely affect the oxidation-reduction reaction in the aqueous solution. The concentration of the surfactant in the aqueous solution should be several hundreds parts per million (ppm). In preferred embodiments of the present invention a cation surfactant, cetyltrimethyl ammonium brombide (CTAB), and a non-ionic surfactant, polyoxyethylene(40) nonylphenyl ether (Igepal®CO-890, Aldrich company) were used together.

Preferably, the pH adjusting agent is a base, and the complexing agent is an amino acid, lactic acid, acetic acid, citric acid, malic acid, maleic acid, oxalic acid, gluconic acid, salt thereof or mixture thereof.

Methods for forming cathode lines on a cathode plate are known in the prior art, for examples forming a metal layer by electroless plating, sputtering deposition and evaporation deposition, followed by patterning the metal layer, which can also be used in the present invention to form the first metal layer. In general, the sputtering deposition and evaporation deposition are more suitable for forming a metal layer having a relatively higher standard redox potential, such as aluminum. The patterning of the first metal layer includes forming a photoresist layer on the first metal layer, imagewise exposing the photoresist layer, developing the exposed photoresist layer to form a patterned photoresist layer, and etching the first metal layer by using the patterned photoresist layer as a mask.

Without further elaboration, it is believed that the above description has adequately enabled the present invention. The following specific examples are, therefore, to be construed as merely illustrative, and not limitative of the remainder of the disclosure in any way whatsoever. All of the publications cited herein, including patents, are here by incorporated by reference in their entirety.

### EXAMPLE 1

### Preparing a Nickel-Carbon Nanotube Field Emission Cathode Plate with a Glass Substrate

A glass substrate was sand blasted to have a coarse surface. The glass substrate was then immersed in sequence in a HF aqueous solution (10 wt %) for one minute, ammonia water (pH=9) for 30 seconds, 3-aminopropyltriethoxysilane solution (3 wt %) for one minute, 25 wt % stannous chloride solution (C-473® catalyst, Rockwood Electrochemicals Asia Ltd.) for three minutes, and HCl solution (10 vol %) for 30 seconds. The glass substrate was then electroless plated with a zinc layer in an electroless plating bath having ZnO (30 g/l), NaCN 25 g/l, pH=12, and a temperature of 25° C.

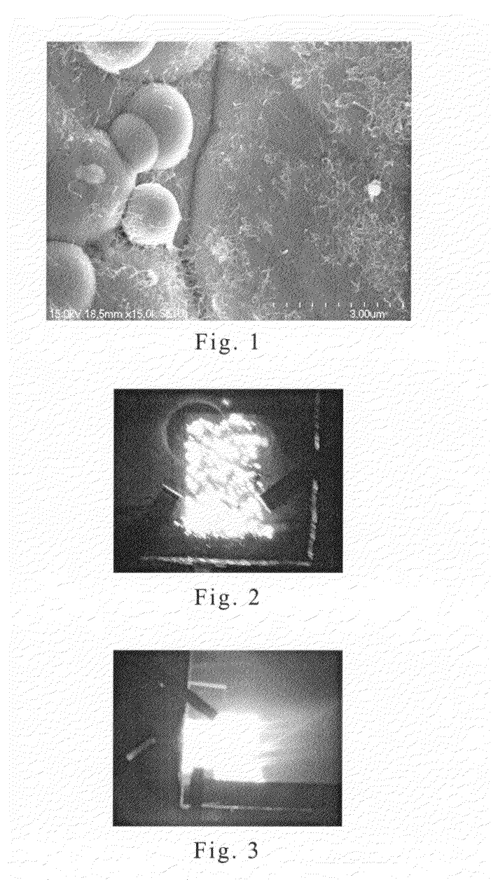

The glass plate having the zinc layer was immersed in an aqueous solution of nickel salt with carbon nanotubes dispersed therein having a composition listed in Table 1 for 30 minutes, and a nickel-carbon nanotube composite layer was formed via chemical displacement reaction. The glass substrate was removed from the solution, washed with deionized water, and heated in a vacuum oven at 400° C. for 30 minutes. As shown in FIG. 1, a photograph taken by a scanning electronic microscopy (SEM), a nickel layer is actually formed on the glass substrate with carbon nanotubes partially buried therein. The glass substrate formed with a nickel-carbon nanotube composite layer, and an anode plate coated with fluorescent powder were assembled. This assembly exhibited a bright luminous effect after an electric voltage being applied thereto, as shown in FIG. 2.

TABLE 1
The composition of an aqueous solution of nickel
salt with carbon nanotubes dispersed therein

| Components | Concentration | |
|---|---|---|
| Nickel sulfate (NiSO₄•6H₂O) | 20 | g/l |
| Sodium lactate (C₃H₅O₃Na) | 40 | g/l |
| Amino acetic acid (C₂H₅O₂N) | 10 | g/l |
| Ammonia water (NH₄OH) | To pH = 4.8 | |
| Surfactant CO-890 | 200 | ppm |
| Surfactant CTAB | 400 | ppm |
| Carbon nanotube | 1 | g/L |

### EXAMPLE 2

### Preparing a Copper Nano-Diamond Field Emission Cathode Plate with a Glass Substrate

A glass substrate was sand blasted to have a coarse surface. The glass substrate was then immersed in sequence in a HF aqueous solution (10 wt %) for one minute, ammonia water (pH=9) for 30 seconds, 3-aminopropyltriethoxysilane solution (5 wt %) for one minute, 25 wt % stannous chloride solution (C-473® catalyst, Rockwood Electrochemicals Asia Ltd.) for three minutes, and HCl solution (10 vol %) for 30 seconds. The glass substrate was then electroless plated with a nickel layer in an electroless plating bath having nickel sulfate ((NiSO₄.6H₂O)) (30 g/l), sodium hypophosphite (30 g/l), pH=5, and a temperature of 85° C.

The glass plate having the zinc layer was immersed in an aqueous solution of copper salt with nano-diamond dispersed therein having a composition listed in Table 2 at a temperature of 60-90° C. for 20 minutes, and a copper-nano diamond composite layer was formed via chemical displacement reaction. The glass substrate was removed from the solution, washed with deionized water, and heated in a vacuum oven at 400° C. for 30 minutes while a hydrogen stream being introducing into the oven (20 sccm). The glass substrate formed with a copper-nano diamond composite layer, and an anode plate coated with fluorescent powder were assembled. This assembly exhibited a bright luminous effect after an electric voltage being applied thereto, as shown in FIG. 3.

TABLE 2
The composition of an aqueous solution of copper
salt with nano-diamond dispersed therein

| Components | Concentration | |
|---|---|---|
| Cupric sulfate (CoSO₄•5H₂O) | 20 | g/l |
| Disodium ethylenediaminetetraacetate (EDTA•2Na) | 35 | g/l |
| Surfactant CO-890 | 200 | ppm |
| Surfactant CTAB | 400 | ppm |
| Nano-diamond | 0.9 | g/L |

### EXAMPLE 3

### Preparing a Nickel-Nano Carbon Fiber Field Emission Cathode Plate with a Glass Substrate

A glass substrate was sand blasted to have a coarse surface. The glass substrate was then immersed in sequence in a HF aqueous solution (10 wt %) for one minute, ammonia water (pH=9) for 30 seconds, 3-aminopropyltriethoxysilane solution (3 wt %) for one minute, 25 wt % stannous chloride solution (C-473® catalyst, Rockwood Electrochemicals Asia Ltd.) for three minutes, and HCl solution (10 vol %) for 30 seconds. The glass substrate was then electroless plated with a zinc layer in an electroless plating bath having ZnO (30 g/l), NaCN 25 g/l, pH=12, and a temperature of 25° C.

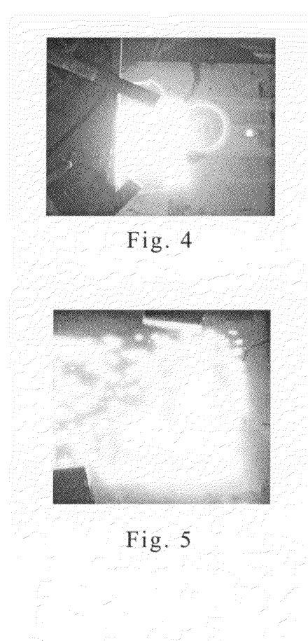

The glass plate having the zinc layer was immersed in an aqueous solution of cobalt salt with nano-carbon fiber dispersed therein having a composition listed in Table 3 for 30 minutes, and a cobalt-nano carbon fiber composite layer was formed via chemical displacement reaction. The glass substrate was removed from the solution, washed with deionized water, and heated in a vacuum oven at 400° C. for 10 minutes. A metal-nano carbon fiber composite layer was observed on the glass substrate via a field effect scanning electronic microscopy (FE-SEM). The glass substrate formed with a cobalt-nano carbon fiber composite layer, and an anode plate coated with fluorescent powder were assembled. This assembly exhibited a bright luminous effect after an electric voltage being applied thereto, as shown in FIG. 4, and a current can be detected via I-V measurement.

TABLE 3
The composition of an aqueous solution of cobalt salt with
nano-carbon fibere dispersed therein

| Components | Concentration |
|---|---|
| Cobalt sulfate (CoSO₄•6H₂O) | 20.11 M |
| Sodium lactate (C₃H₅O₃Na) | 0.36 M |
| Amino acetic acid (C₂H₅O₂N) | 0.13 M |
| Ammonia water (NH₄OH) | To pH = 9 |
| Surfactant CO-890 | 200 ppm |
| Surfactant CTAB | 400 ppm |
| Nano-carbon fiber | 1.2 g/L |

### EXAMPLE 4

### Preparing a Nickel-Carbon Nanotube Field Emission Cathode Plate with a Glass Substrate

A glass substrate was washed clean and dried, and then put into a sputtering machine, in which a layer of aluminum was deposited under appropriate conditions to a thickness of 20 nm. The glass plate having the aluminum layer was immersed in an aqueous solution of nickel sulfate with carbon nanotubes dispersed therein having a composition listed in Table 4, and a nickel-carbon nanotube composite layer was formed via chemical displacement reaction. The glass substrate was removed from the solution, washed with deionized water, and heated in a vacuum oven at 400° C. for 10 minutes. The glass substrate formed with a nickel-carbon nanotube composite layer, and an anode plate coated with fluorescent powder were assembled. This assembly exhibited a bright luminous effect after an electric voltage being applied thereto, as shown in FIG. 5.

TABLE 4
The composition of an aqueous solution of nickel sulfate with
carbon nanotubes dispersed therein

| Components | Concentration |
|---|---|
| Nickel sulfate (NiSO₄•6H₂O) | 20 g/l |
| Sodium citrate (Na₃C₆H₅O₇) | 0.36 M |
| Ammonia water (NH₄OH) | To pH = 9 |
| Surfactant CO-890 | 200 ppm |
| Surfactant CTAB | 400 ppm |
| Carbon nanotube | 1 g/L |

Although the present invention has been described with reference to specific details of certain embodiments thereof, it is not intended that such details should be regarded as limitations upon the scope of the invention except as and to the extent that they are included in the accompanying claims. Many modifications and variations are possible in light of the above disclosure.

1. A process for preparing a nano-carbon material field emission cathode plate comprising the following steps:
a) forming a layer of a first metal on a substrate; and
b) immersing the substrate in an aqueous solution of a salt of a second metal with a nano-carbon material dispersed therein to form a layer of the second metal on the first metal layer with the nano-carbon material partially embedded in the second metal layer, wherein, due to a difference between two standard redox potentials of the first metal and the second metal, ions of the second metal in the aqueous solution are reduced to elemental metal while the first metal is oxidized.

2. The process of claim 1, wherein the first metal is iron, cobalt, nickel, tin, zinc, aluminum or a mixture thereof; and the second metal is copper, gold, palladium, platinum, silver, nickel, cobalt, or a mixture thereof.

3. The process of claim 2, wherein the first metal is aluminum.

4. The process of claim 2, wherein the first metal is zinc, and the second metal is nickel; the first metal is nickel, and the second metal is copper; the first metal is zinc, and the second metal is cobalt; or the first metal is aluminum, and the second metal is nickel.

5. The process of claim 1, wherein step a) comprises forming the first metal layer on the substrate by sputtering deposition, evaporating deposition, or electroless plating.

6. The process of claim 5, wherein the first metal layer is formed by sputtering deposition.

7. The process of claim 5, wherein the first metal layer is formed by electroless plating.

8. The process of claim 1 further comprising:
c) removing the substrate from the aqueous solution, washing the substrate with water, and heating the substrate under vacuum to activate the nano-carbon material partially embedded in the second metal layer.

9. The process of claim 1, wherein the substrate is a glass substrate or a glass substrate with silicon deposited thereon.

10. The process of claim 1, wherein the nano-carbon material is carbon nanotube, nano-carbon fiber or nano-diamond.

11. The process of claim 1, wherein the aqueous solution in step b) is kept at a temperature of 60 to 80° C.

12. The process of claim 8, wherein the heating is carried out at 200-500° C. for 10-60 minutes.

13. The process of claim 12, wherein the heating is carried out at 400° C. for 10-30 minutes.

14. The process of claim 1, wherein the difference between two standard redox potentials of the first metal and the second metal is greater than 200 mV.

15. The process of claim 1, wherein the aqueous solution of the second metal salt in step b) may contain a surfactant or a dispersing agent to enhance the dispersion of the nano-carbon material in the aqueous solution.

16. The process of claim 15, wherein the aqueous solution further contains a complexing agent.

17. The process of claim 16, wherein the aqueous solution further contains a pH adjusting agent.

18. The process of claim 1, wherein the pH adjusting agent is a base, and the complexing agent is an amino acid, lactic acid, acetic acid, citric acid, malic acid, maleic acid, oxalic acid, gluconic acid, a salt thereof or a mixture thereof.

19. The process of claim 1, wherein step a) further comprises patterning the first metal layer.

20. The process of claim 19, wherein the patterning comprising forming a photoresist layer on the first metal layer, imagewise exposing the photoresist layer, developing the exposed photoresist layer to form a patterned photoresist layer, and etching the first metal layer by using the patterned photoresist layer as a mask.
